(19) United States
(12) Patent Application Publication
(10) Pub. No.: US 2026/0309800 A1
(43) Pub. Date: Oct. 8, 2026

(54) IN-VEHICLE CONTROL DEVICE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Yuki NARITA, Yokkaichi-shi, Mie (JP)

(73) Assignees: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(21) Appl. No.: 19/483,376

(22) PCT Filed: May 16, 2023
(86) PCT No.: PCT/JP2023/018240

§ 371 Date: Nov. 11, 2025

(51) Int. Cl. G01R 31/392; B60R 16/033; G01R 31/3842; H02J 7/00; H02J 7/34; H02J 7/90

(52) U.S. Cl. CPC G01R 31/392; B60R 16/033; G01R 31/3842; H02J 7/34; H02J 7/875; H02J 7/971; H02J 2207/20

(57) ABSTRACT

An in-vehicle control device includes a voltage conversion unit and a control unit. The voltage conversion unit includes a first switch and a second switch connected in series between a first conductive path and ground, a third switch and an element unit (for example, a fourth switch) connected in series between a second conductive path and the ground, and an inductor. The voltage conversion unit performs a discharging operation of turning the third switch on and off, interrupting a current flowing to the ground side through the element unit at least when the third switch is in an on state, and maintaining the second switch in an on state. The control unit causes the voltage conversion unit to perform the discharging operation when a discharging condition is satisfied.

### CROSS-REFERENCE TO RELATED APPLICATIONS

This application is the U.S. national stage of PCT/JP2023/018240 filed on May 16, 2023, the content of which is incorporated herein.

### TECHNICAL FIELD

The present disclosure relates to an in-vehicle control device.

### BACKGROUND

JP 2018-068019A discloses a backup device. This backup device has a function of quickly discharging electricity from a power storage unit (second power supply unit) when power supply from a power supply unit (first power supply unit) is interrupted.

It is known that devices having the above function determine a degree of deterioration (for example, state of health (SOH)) of the power storage unit. The degree of deterioration is determined when the power storage unit is charged or discharged. However, since the power storage unit needs to be charged in order to perform backup, the power storage unit needs to be discharged in advance before being charged. That is, regardless of whether the degree of deterioration is determined when charging or discharging, it is necessary to discharge the power storage unit in order to determine the degree of deterioration. In the case of causing the power storage unit to discharge power to ground, it is conceivable to provide a dedicated discharge circuit. However, providing the dedicated discharge circuit leads to an increase in the number of components.

The present disclosure provides a technology that makes it possible to cause the power storage unit to discharge power to ground by utilizing a voltage conversion unit that can charge and discharge the power storage unit.

### SUMMARY

An in-vehicle control device disclosed herein includes: a voltage conversion unit to be provided between a power storage unit and a power path that supplies power from a power supply unit to a load; and a control unit configured to control the voltage conversion unit, wherein the voltage conversion unit performs a first conversion operation of converting a voltage applied to a first conductive path on a power path side and applying the converted voltage to a second conductive path on a power storage unit side, and a second conversion operation of converting a voltage applied to the second conductive path and applying the converted voltage to the first conductive path, the voltage conversion unit has a first switch and a second switch connected in series between the first conductive path and ground, a third switch and an element unit connected in series between the second conductive path and the ground, and an inductor, the first switch is disposed closer to the first conductive path than the second switch is, the third switch is disposed closer to the second conductive path than the element unit is, the element unit is a fourth switch or a diode and is capable of interrupting a current flowing through the element unit toward the ground, one end of the inductor is electrically connected to a portion between the first switch and the second switch, another end of the inductor is electrically connected to a portion between the third switch and the element unit, the voltage conversion unit performs a discharging operation of turning the third switch on and off, interrupting the current flowing to the ground side through the element unit at least when the third switch is in an on state, and maintaining the second switch in an on state, and the control unit causes the voltage conversion unit to perform the discharging operation when a discharging condition is satisfied.

### Advantageous Effects

The technology according to the present disclosure can cause a power storage unit to discharge power to ground by utilizing a voltage conversion unit that can charge and discharge the power storage unit.

### BRIEF DESCRIPTION OF DRAWINGS

FIG. 1 is a configuration diagram schematically illustrating a configuration of an in-vehicle system including an in-vehicle control device of a first embodiment.

FIG. 2 is an explanatory diagram illustrating a flow of current when a discharging operation is performed in the in-vehicle control device of the first embodiment.

FIG. 3 is a flowchart illustrating a flow of processing performed by a control unit of the first embodiment.

FIG. 4 is a flowchart illustrating a flow of processing performed by the control unit of a second embodiment.

### DETAILED DESCRIPTION OF PREFERRED EMBODIMENTS

Hereinafter, embodiments according to the present disclosure are listed and illustrated.

In a first aspect, an in-vehicle control device including: a voltage conversion unit to be provided between a power storage unit and a power path that supplies power from a power supply unit to a load; and a control unit configured to control the voltage conversion unit, wherein the voltage conversion unit performs a first conversion operation of converting a voltage applied to a first conductive path on a power path side and applying the converted voltage to a second conductive path on a power storage unit side, and a second conversion operation of converting a voltage applied to the second conductive path and applying the converted voltage to the first conductive path, the voltage conversion unit has a first switch and a second switch connected in series between the first conductive path and ground, a third switch and an element unit connected in series between the second conductive path and the ground, and an inductor, the first switch is disposed closer to the first conductive path than the second switch is, the third switch is disposed closer to the second conductive path than the element unit is, the element unit is a fourth switch or a diode and is capable of interrupting a current flowing through the element unit toward the ground, one end of the inductor is electrically connected to a portion between the first switch and the second switch, another end of the inductor is electrically connected to a portion between the third switch and the element unit, the voltage conversion unit performs a discharging operation of turning the third switch on and off, interrupting the current flowing to the ground side through the element unit at least when the third switch is in an on state, and maintaining the second switch in an on state, and the control unit causes the voltage conversion unit to perform the discharging operation when a discharging condition is satisfied.

The in-vehicle control device can charge the power storage unit by causing the voltage conversion unit to perform the first conversion operation, and can discharge the power storage unit by causing the voltage conversion unit to perform the second conversion operation. Furthermore, the in-vehicle control device can cause the power storage unit to discharge power to the ground by causing the voltage conversion unit to perform the discharging operation. That is, the in-vehicle control device can cause the power storage unit to discharge power to the ground using the voltage conversion unit that charges and discharges the power storage unit as described above. Moreover, the voltage conversion unit turns the third switch on and off when performing the discharging operation, and interrupts the current flowing to the ground side through the element unit at least when the third switch is in the on state. This can suppress discharging current from the power storage unit. That is, the in-vehicle control device can suppress the discharging current while causing the power storage unit to discharge power to the ground.

In a second aspect, the in-vehicle control device according to the first aspect, in which the control unit determines whether the power storage unit is in a deteriorated state based on a voltage and a discharging current of the power storage unit during the discharging operation.

As deterioration of the power storage unit progresses, the internal resistance of the power storage unit increases, and the power storage unit eventually reaches a deteriorated state that requires replacement or the like. The internal resistance of the power storage unit is measured based on the voltage and discharging current of the power storage unit during the discharging operation. That is, the in-vehicle control device can determine whether the power storage unit is in a deteriorated state based on the voltage and the discharging current of the power storage unit during the discharging operation.

In a third aspect, the in-vehicle control device according to the second aspect, in which the control unit causes the voltage conversion unit to perform the discharging operation so that the discharging current of the power storage unit becomes constant for at least a part of a predetermined period during the discharging operation, and determines whether the power storage unit is in the deteriorated state based on the voltage and the discharging current of the power storage unit during the predetermined period.

When the discharging current of the power storage unit is constant, the in-vehicle control device can accurately measure the internal resistance of the power storage unit, thereby easily accurately determining whether the power storage unit is in a deteriorated state.

In a fourth aspect, the in-vehicle control device according to the second or the third aspect, in which the discharging condition is that a start switch of a vehicle is changed to an on state.

The in-vehicle control device can determine whether the power storage unit is in a deteriorated state at a timing when use of the vehicle is started.

In a fifth aspect, the in-vehicle control device according to the first aspect, in which the control unit causes the voltage conversion unit to perform the discharging operation and then the first conversion operation, and determines whether the power storage unit is in a deteriorated state based on a voltage and a charging current of the power storage unit during the first conversion operation.

As the deterioration of the power storage unit progresses, the internal resistance of the power storage unit increases, and the power storage unit eventually reaches a deteriorated state that requires replacement or the like. The internal resistance of the power storage unit is measured based on the voltage and the charging current of the power storage unit during charging. That is, the in-vehicle control device can determine whether the power storage unit is in a deteriorated state based on the voltage and the charging current of the power storage unit during charging.

In a sixth aspect, the in-vehicle control device according to the fifth aspect, in which the control unit causes the voltage conversion unit to perform the first conversion operation so that the charging current of the power storage unit becomes constant for at least a part of a predetermined period during the first conversion operation, and determines whether the power storage unit is in the deteriorated state based on the voltage and the charging current of the power storage unit during the predetermined period.

When the charging current of the power storage unit is constant, the in-vehicle control device can accurately measure the internal resistance of the power storage unit, thereby easily accurately determining whether the power storage unit is in a deteriorated state.

In a seventh aspect, the in-vehicle control device according to the fifth or the sixth aspect, in which when a start switch of a vehicle is changed to an on state, or after the start switch is changed to an on state and the control unit causes the voltage conversion unit to perform the discharging operation, the control unit causes the voltage conversion unit to perform the first conversion operation, and determines whether the power storage unit is in the deteriorated state based on the voltage and the charging current of the power storage unit during the first conversion operation.

The in-vehicle control device can determine whether the power storage unit is in a deteriorated state at the timing when use of the vehicle is started.

In an eighth aspect, the in-vehicle control device according to any one of the first to the seventh aspects, in which the discharging condition is that a start switch of a vehicle is changed to an off state.

The in-vehicle control device can discharge the power storage unit by utilizing the time during which the vehicle is parked.

In a ninth aspect, the in-vehicle control device according to any one of the second to the fourth aspects and the eighth aspect, in which the control unit measures an internal resistance of the power storage unit based on the voltage and the discharging current of the power storage unit during the discharging operation, and determines that the power storage unit is in the deteriorated state when a rate of increase of a measured value with respect to an initial value of the internal resistance of the power storage unit exceeds a threshold value.

The in-vehicle control device can determine whether the power storage unit is in a deteriorated state by simple processing.

In a tenth aspect, the in-vehicle control device according to any one of the fifth to the eighth aspects, in which the control unit measures an internal resistance of the power storage unit based on the voltage and the charging current of the power storage unit during the first conversion operation, and determines that the power storage unit is in the deteriorated state when a rate of increase of a measured value with respect to an initial value of the internal resistance of the power storage unit exceeds a threshold value.

The in-vehicle control device can determine whether the power storage unit is in a deteriorated state by simple processing.

### First Embodiment

### Configuration of In-Vehicle System 1

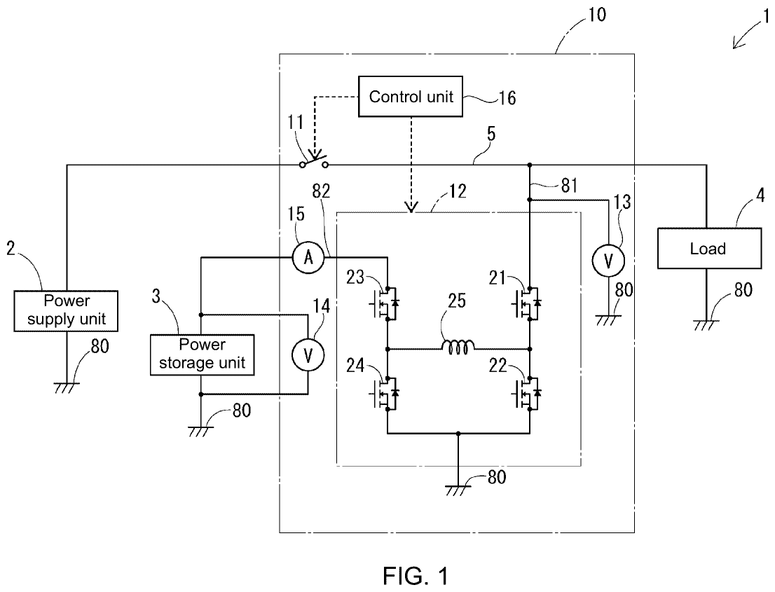

FIG. 1 illustrates an in-vehicle system 1 including an in-vehicle control device 10. The in-vehicle system 1 is for installation in a vehicle. The in-vehicle system 1 includes a power supply unit 2, a power storage unit 3, a load 4, and a power path 5.

The power supply unit 2 is an in-vehicle power supply capable of supplying power to the load 4. The power supply unit 2 is configured by a known in-vehicle battery such as a lead battery. The power supply unit 2 may be configured by a battery other than a lead battery, and may have a power supply means other than the battery instead of or in addition to the battery. A positive electrode of the power supply unit 2 is electrically connected to the power path 5. An output voltage of the power supply unit 2 is applied to the power path 5. A negative electrode of the power supply unit 2 is electrically connected to ground 80. The power supply unit 2 supplies power to the power path 5, and supplies power to the load 4 via the power path 5.

The power storage unit 3 functions as a backup power supply at least when power supply from the power supply unit 2 is interrupted. The power storage unit 3 may be configured to include a capacitor (for example, an electric double layer capacitor (EDLC) or a lithium ion capacitor (LiC)), may be configured to include a battery, and may be configured to include another power storage means. A positive electrode of the power storage unit 3 is electrically connected to a second conductive path 82. A negative electrode of the power storage unit 3 is electrically connected to the ground 80. A voltage of the power storage unit 3 is an output voltage of the power storage unit 3, and is a charging voltage of the power storage unit 3. The voltage of the power storage unit 3 may be greater or smaller than the output voltage of the power supply unit 2. The output voltage of the power storage unit 3 is applied to the second conductive path 82. The power storage unit 3 supplies power to the load 4 via the power path 5 at least when the power supply from the power supply unit 2 is interrupted.

In this specification, unless otherwise specified, the voltage refers to a voltage relative to the potential of the ground 80 (for example, 0 V), and is a potential difference from the potential of the ground 80.

The load 4 is an electrical component mounted in the vehicle. The load 4 operates by receiving power supplied via the power path 5.

The power path 5 is a path through which power from the power supply unit 2 is transmitted and is a path through which the power from the power supply unit 2 is supplied to the load 4.

### Configuration of In-Vehicle Control Device 10

The in-vehicle control device 10 is provided in the in-vehicle system 1. The in-vehicle control device 10 includes a relay 11, a voltage conversion unit 12, voltage detection units 13 and 14, a current detection unit 15, and a control unit 16.

The relay 11 is provided in the power path 5. The relay 11 may be configured by a semiconductor switch such as a field effect transistor (FET), or may be configured by a mechanical relay. The relay 11 allows bidirectional energization when in an on state, and interrupts the bidirectional energization when in an off state.

The voltage conversion unit 12 is provided between the power path 5 and the power storage unit 3 (specifically, a portion of the power path 5 closer to the load 4 than the relay 11 is). The voltage conversion unit 12 performs a first conversion operation of converting a voltage applied to a first conductive path 81 on the power path 5 side and applying the converted voltage to the second conductive path 82 on the power storage unit 3 side. The first conversion operation may be a step-up operation or a step-down operation. The voltage conversion unit 12 performs the second conversion operation of converting a voltage applied to the second conductive path 82 and applying the converted voltage to the first conductive path 81. The second conversion operation may be the step-up operation or the step-down operation.

The voltage conversion unit 12 has a first switch 21, a second switch 22, a third switch 23, a fourth switch 24, and an inductor 25. The first switch 21, the second switch 22, the third switch 23, and the fourth switch 24 (hereinafter also referred to as switches 21, 22, 23, and 24) are configured by semiconductor switches. In the present embodiment, the switches 21, 22, 23, and 24 are N-channel metal-oxide semiconductor field effect transistors (MOSFETs). The switches 21, 22, 23, and 24 are turned on and off when given an on/off signal. The on/off signal is, for example, a pulse width modulation (PWM) signal.

The first switch 21 and the second switch 22 are connected in series between the first conductive path 81 and the ground 80. The first switch 21 is disposed closer to the first conductive path 81 than the second switch 22 is. One end (specifically, a drain) of the first switch 21 is electrically connected to the first conductive path 81. The other end (specifically, a source) of the first switch 21 is electrically connected to one end (specifically, a drain) of the second switch 22. The other end (specifically, a source) of the second switch 22 is electrically connected to the ground 80.

The third switch 23 and the fourth switch 24 are connected in series between the second conductive path 82 and the ground 80. The third switch 23 is disposed closer to the second conductive path 82 than the fourth switch 24 is. One end (specifically, a drain) of the third switch 23 is electrically connected to the second conductive path 82. The other end (specifically, a source) of the third switch 23 is electrically connected to one end (specifically, a drain) of the fourth switch 24. The other end (specifically, a source) of the fourth switch 24 is electrically connected to the ground 80.

One end of the inductor 25 is electrically connected to a portion between the other end of the first switch 21 and the one end of the second switch 22. The other end of the inductor 25 is electrically connected to a portion between the other end of the third switch 23 and the one end of the fourth switch 24.

The voltage conversion unit 12 performs a first step-down operation of stepping down the voltage applied to the first conductive path 81 by turning the first switch 21 on and off. and applying the stepped-down voltage to the second conductive path 82. In the first step-down operation, the voltage conversion unit 12 turns the second switch 22 on and off in a manner complementary to the first switch 21.

The voltage conversion unit 12 performs a first step-up operation of stepping up the voltage applied to the first conductive path 81 by turning the fourth switch 24 on and off, and applying the stepped up voltage to the second conductive path 82. In the first step-up operation, the voltage conversion unit 12 turns the third switch 23 on and off in a manner complementary to the fourth switch 24.

The voltage conversion unit 12 performs a second step-down operation of stepping down the voltage applied to the second conductive path 82 by turning the third switch 23 on and off, and applying the stepped-down voltage to the first conductive path 81. In the second step-down operation, the voltage conversion unit 12 turns the fourth switch 24 on and off in a manner complementary to the third switch 23.

The voltage conversion unit 12 performs a second step-up operation of stepping up the voltage applied to the second conductive path 82 by turning the second switch 22 on and off, and applying the stepped-up voltage to the first conductive path 81. In the second step-up operation, the voltage conversion unit 12 turns the first switch 21 on and off in a manner complementary to the second switch 22.

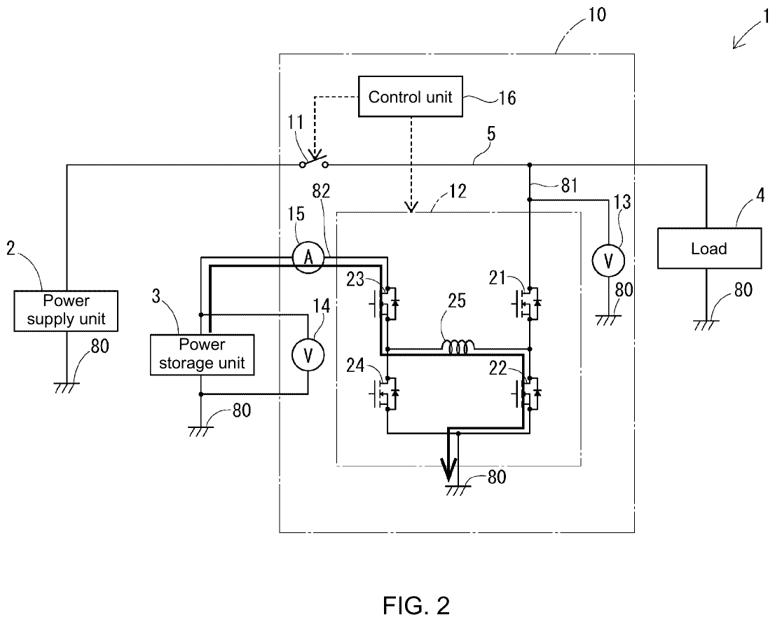

The voltage conversion unit 12 performs a discharging operation of turning the third switch 23 on and off, turning the fourth switch 24 on and off in a manner complementary to the third switch 23, and maintaining the second switch in an on state. Thus, as illustrated in FIG. 2, the power storage unit 3 discharges power to the ground 80 via the third switch 23, the inductor 25, and the second switch 22. Moreover, when performing the discharging operation, the voltage conversion unit 12 turns the third switch 23 on and off, and turns the fourth switch 24 on and off in a manner complementary to the third switch 23, and thus the power storage unit 3 discharges power to the ground 80 with a suppressed discharging current.

The voltage detection unit 13 detects the voltage of the first conductive path 81. The voltage detection unit 13 is configured as, for example, a known voltage detection circuit. The voltage detection unit 13 outputs a signal indicating a detected value. The signal indicating the detected value is input to the control unit 16.

The voltage detection unit 14 detects the voltage of the power storage unit 3. The voltage detection unit 14 detects the voltage across the ends of the power storage unit 3. The voltage detection unit 14 detects the voltage of the second conductive path 82. The voltage detection unit 14 is configured as, for example, a known voltage detection circuit. The voltage detection unit 14 outputs a signal indicating a detected value. The signal indicating the detected value is input to the control unit 16.

The current detection unit 15 detects the discharging current and the charging current of the power storage unit 3. The current detection unit 15 detects the current flowing through the second conductive path 82. The current detection unit 15 is configured by, for example, a known current sensor. The current detection unit 15 outputs a signal indicating a detected value. The signal indicating the detected value is input to the control unit 16.

The control unit 16 is configured to include, for example, a microcomputer. The control unit 16 includes a CPU, a memory, and the like. The control unit 16 includes a drive circuit that drives the switches 21, 22, 23, and 24. The control unit 16 detects the voltage of the first conductive path 81 based on the signal output from the voltage detection unit 13. The control unit 16 detects the voltage of the second conductive path 82 and the voltage of the power storage unit 3 based on the signal output from the voltage detection unit 14. The control unit 16 detects the discharging current and the charging current of the power storage unit 3 based on the signal output from the current detection unit 15. The control unit 16 controls the relay 11. The control unit 16 controls the switches 21, 22, 23, and 24 to control the voltage conversion unit 12.

When causing the voltage conversion unit 12 to perform the first conversion operation, the control unit 16 performs feedback control so that the voltage of the second conductive path 82 approaches a target voltage. When causing the voltage conversion unit 12 to perform the second conversion operation, the control unit 16 performs feedback control so that the voltage of the first conductive path 81 approaches the target voltage. The feedback control is, for example, PI control or PID control. The target voltage may be a value set by the control unit 16, or a value instructed by an external device such as an external electronic control unit (ECU).

When causing the voltage conversion unit 12 to perform the first conversion operation, the control unit 16 determines a duty of the on/off signal so as to bring the voltage of the second conductive path 82 closer to the target voltage by performing known feedback calculation such as PID calculation or PI calculation based on deviation between the voltage of the second conductive path 82 and the target voltage. When causing the voltage conversion unit 12 to perform the second conversion operation, the control unit 16 determines the duty of the on/off signal so as to bring the voltage of the first conductive path 81 closer to the target voltage by performing the known feedback calculation such as PID calculation or PI calculation based on deviation between the voltage of the first conductive path 81 and the target voltage.

The duty refers to the on-time relative to the switching cycle. The control unit 16 periodically updates the duty by periodically performing the feedback calculation. The duties include a first duty for controlling on/off of the first switch 21 in the first step-down operation, a second duty for controlling on/off of the second switch 22 in the second step-up operation, a third duty for controlling on/off of the third switch 23 in the second step-down operation, and a fourth duty for controlling on/off of the fourth switch 24 in the first step-up operation.

When causing the voltage conversion unit 12 to perform the first step-down operation, the control unit 16 determines the first duty and outputs an on/off signal for the determined first duty to the gate of the first switch 21. Further, the control unit 16 outputs an on/off signal, which is complementary to the on/off signal output to the first switch 21, to the second switch 22. Thus, synchronous rectification control is performed when the first step-down operation is performed.

When causing the voltage conversion unit 12 to perform the first voltage step-up operation, the control unit 16 determines the fourth duty and outputs an on/off signal for the determined fourth duty to the gate of the fourth switch 24. Further, the control unit 16 outputs an on/off signal, which is complementary to the on/off signal output to the fourth switch 24, to the third switch 23. Thus, the synchronous rectification control is performed when the first voltage step-up operation is performed.

When causing the voltage conversion unit 12 to perform the second voltage step-down operation, the control unit 16 determines the third duty and outputs an on/off signal for the determined third duty to the gate of the third switch 23. Further, the control unit 16 outputs an on/off signal, which is complementary to the on/off signal output to the third switch 23, to the fourth switch 24. Thus, the synchronous rectification control is performed when the second voltage step-down operation is performed.

When causing the voltage conversion unit 12 to perform the second step-up operation, the control unit 16 determines the second duty and outputs an on/off signal for the determined second duty to the gate of the second switch 22. Further, the control unit 16 outputs an on/off signal, which is complementary to the on/off signal output to the second switch 22, to the first switch 21. Thus, the synchronous rectification control is performed when the second step-up operation is performed.

When the charging condition is satisfied, the control unit 16 causes the voltage conversion unit 12 to perform the first conversion operation to charge the power storage unit 3 based on the power from the power supply unit 2. The charging condition may be that the voltage of the power storage unit 3 falls below a threshold value, that power supply from the power supply unit 2 to the load 4 starts, or another condition.

When the voltage of the power path 5 falls below a low voltage threshold value, the control unit 16 switches the relay 11 to the off state and causes the voltage conversion unit 12 to perform the second conversion operation to cause the power storage unit 3 to supply power to the load 4.

When the discharging condition is satisfied, the control unit 16 causes the voltage conversion unit 12 to perform the discharging operation. Specifically, the control unit 16 controls the first switch 21 to an off state, controls the second switch 22 to an on state, turns the third switch 23 on and off, and turns the fourth switch 24 on and off in a manner complementary to the third switch 23.

The discharging condition may be, for example, that the start switch of the vehicle is switched to the off state, that the start switch of the vehicle is switched to the on state, or another condition. Note that the start switch is an ignition switch, a power switch, or the like. The control unit 16 detects the on/off state of the start switch by, for example, receiving a signal indicating the on/off state of the start switch from the external ECU.

The control unit 16 determines whether the power storage unit 3 is in a deteriorated state based on the voltage and the discharging current of the power storage unit 3 during the discharging operation. The control unit 16 causes the voltage conversion unit 12 to perform the discharging operation so that the discharging current of the power storage unit 3 is constant for at least a part of a predetermined period during the discharging operation, and determines whether the power storage unit 3 is in the deteriorated state based on the voltage and the discharging current of the power storage unit 3 during the predetermined period.

The control unit 16 measures the internal resistance of the power storage unit 3 based on the voltage and the discharging current of the power storage unit 3 during the discharging operation, and determines that the power storage unit 3 is in the deteriorated state when the rate of increase of the measured value relative to the initial value of the internal resistance of the power storage unit 3 exceeds the threshold value. Note that the initial value of the internal resistance may be a value stored in advance or an actually measured value.

After performing the discharging operation, when a post-discharging charging condition is satisfied, the control unit 16 causes the voltage conversion unit 12 to perform the first conversion operation. Thus, the power storage unit 3 is charged using power from the power supply unit 2.

The post-discharging charging condition may be that the discharging operation has ended, or that a predetermined start condition has been satisfied after the discharging operation has ended. For example, when the discharging condition is that “the start switch has been switched to the off state”, the post-discharging charging condition may be that the discharging operation has ended, or that the start switch has been switched to the on state. When the discharging condition is that “the start switch has been switched to the on state”, the post-discharging charging condition is preferably that the discharging operation has ended.

### Operation of In-Vehicle Control Device 10

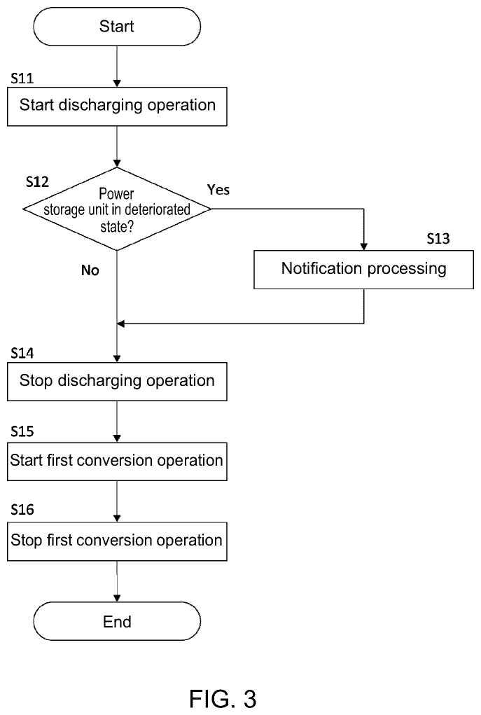

The control unit 16 performs the processing illustrated in FIG. 3. When the discharging condition is satisfied, the control unit 16 causes the voltage conversion unit 12 to start the discharging operation in step S11. The control unit 16 causes the voltage conversion unit 12 to perform the discharging operation so that the discharging current of the power storage unit 3 becomes constant.

When the discharging current of the power storage unit 3 becomes constant, the control unit 16 determines in step S12 whether the power storage unit 3 is in the deteriorated state. Specifically, the control unit 16 measures the internal resistance of the power storage unit 3 based on the voltage and the discharging current of the power storage unit 3. The internal resistance is a value obtained by dividing the amount of voltage change in a predetermined determination period by the discharging current. The control unit 16 calculates the rate of increase of the measured value relative to the initial value of the internal resistance of the power storage unit 3, and determines whether the calculated rate of increase exceeds the threshold value. If it is determined that the rate of increase exceeds the threshold value, the control unit 16 determines that the power storage unit 3 is in the deteriorated state. If it is determined that the rate of increase does not exceed the threshold value, the control unit 16 determines that the power storage unit 3 is not in the deteriorated state.

If it is determined that that the power storage unit 3 is in the deteriorated state, the control unit 16 performs notification processing in step S13. The notification processing is processing of notifying the external ECU that the power storage unit 3 is in the deteriorated state.

If it is determined that the power storage unit 3 is not in the deteriorated state, or after performing the notification processing, the control unit 16 stops the discharging operation of the voltage conversion unit 12 in step S14.

After stopping the discharging operation of the voltage conversion unit 12, when the post discharging charging condition is satisfied, the control unit 16 causes the voltage conversion unit 12 to start the first conversion operation in step S15. When charging of the power storage unit 3 is completed, the control unit 16 stops the first conversion operation in step S16.

### Effects of In-Vehicle Control Device 10

The in-vehicle control device 10 can charge the power storage unit 3 by causing the voltage conversion unit 12 to perform the first conversion operation, and can discharge the power storage unit 3 by causing the voltage conversion unit 12 to perform the second conversion operation. Furthermore, the in-vehicle control device 10 can cause the power storage unit 3 to discharge power to the ground 80 by causing the voltage conversion unit 12 to perform the discharging operation. That is, the in-vehicle control device 10 can cause the power storage unit 3 to discharge power to the ground 80 using the voltage conversion unit 12 that charges and discharges the power storage unit 3. Moreover, when performing the discharging operation, the voltage conversion unit 12 turns the third switch 23 on and off, and turns the fourth switch 24 on and off in a manner complementary to the third switch 23. Therefore, the discharging current from the power storage unit 3 is suppressed. That is, the in-vehicle control device 10 can suppress the discharging current while causing the power storage unit 3 to discharge power to the ground 80.

As the deterioration of the power storage unit 3 progresses, the internal resistance increases, and eventually the power storage unit 3 reaches the deteriorated state requiring replacement or the like. The internal resistance of the power storage unit 3 is measured based on the voltage and the discharging current of the power storage unit 3 during the discharging operation. That is, the in-vehicle control device 10 can determine whether the power storage unit 3 is in the deteriorated state based on the voltage and the discharging current of the power storage unit 3 during the discharging operation.

When the discharging current of the power storage unit 3 is constant, the in-vehicle control device 10 can accurately measure the internal resistance of the power storage unit 3, thereby easily accurately determining whether the power storage unit 3 is in the deteriorated state.

When the discharging condition is that “the start switch of the vehicle is switched to the on state”, the in-vehicle control device 10 can determine whether the power storage unit 3 is in the deteriorated state at the timing when the use of the vehicle is started.

When the discharging condition is that “the start switch of the vehicle is switched to the off state”, the in-vehicle control device 10 can discharge the power storage unit 3 by utilizing the time during which the vehicle is parked.

The in-vehicle control device 10 can determine whether the power storage unit 3 is in the deteriorated state by simple processing.

### Second Embodiment

In the first embodiment, a configuration is described in which it is determined whether the power storage unit 3 is in the deteriorated state during a discharging operation. In contrast, in the second embodiment, a configuration is described in which it is determined whether the power storage unit 3 is in the deteriorated during the first conversion operation after the discharging operation. Note that the in-vehicle control device 10 of the second embodiment has the same configuration as that illustrated in FIG. 1. Therefore, the second embodiment will be described with reference to FIG. 1.

The control unit 16 causes the voltage conversion unit 12 to perform the discharging operation and then the first conversion operation, and determines whether the power storage unit 3 is in the deteriorated state based on the voltage and the charging current of the power storage unit 3 during the first conversion operation. As the deterioration of the power storage unit 3 progresses, the internal resistance increases, and eventually the power storage unit 3 reaches the deteriorated state requiring replacement or the like. The internal resistance of the power storage unit 3 is measured based on the voltage and the charging current of the power storage unit 3 during charging. That is, the in-vehicle control device 10 can determine whether the power storage unit 3 is in the deteriorated state based on the voltage and the charging current of the power storage unit 3 during charging.

The control unit 16 causes the voltage conversion unit 12 to perform the first conversion operation so that the charging current of the power storage unit 3 is constant for at least a part of a predetermined period during the first conversion operation, and determines whether the power storage unit 3 is in the deteriorated state based on the voltage and the charging current of the power storage unit 3 for the predetermined period. When the charging current of the power storage unit 3 is constant, the in-vehicle control device 10 can accurately measure the internal resistance of the power storage unit 3, thereby easily accurately determining whether the power storage unit 3 is in the deteriorated state.

When the start switch of the vehicle is changed to the on state, or after the start switch is changed to the on state and the control unit 16 causes the voltage conversion unit 12 to perform the discharging operation, the control unit 16 causes the voltage conversion unit 12 to perform the first conversion operation, and determines whether the power storage unit 3 is in the deteriorated state based on the voltage and the charging current of the power storage unit 3 during the first conversion operation. With this configuration, the in-vehicle control device 10 can determine whether the power storage unit 3 is in the deteriorated state at the timing when use of the vehicle is started.

Alternatively, after the start switch is switched to the off state and the control unit 16 causes the voltage conversion unit 12 to perform the discharging operation, the control unit 16 causes the voltage conversion unit 12 to perform the first conversion operation, and determines whether the power storage unit 3 is in the deteriorated state based on the voltage and the charging current of the power storage unit 3 during the first conversion operation. With this configuration, the in-vehicle control device 10 can discharge the power storage unit 3 by utilizing the time during which the vehicle is parked.

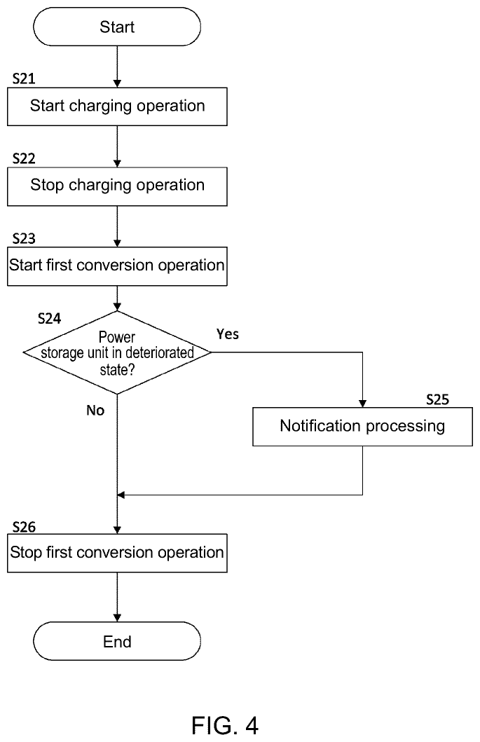

The control unit 16 performs the processing illustrated in FIG. 4. When the discharging condition is satisfied, the control unit 16 causes the voltage conversion unit 12 to start the discharging operation in step S21. When a discharging termination condition is satisfied, the control unit 16 causes the voltage conversion unit 12 to stop the discharging operation in step S22. The discharging termination condition is set so that sufficient time is ensured to determine the deteriorated state in the first conversion operation that is performed thereafter. The discharging termination condition may be that a predetermined discharging time has elapsed, that the charging voltage of the power storage unit 3 has fallen below a discharging termination voltage, or another condition.

After stopping the discharging operation, the control unit 16 causes the voltage conversion unit 12 to start the first conversion operation. The control unit 16 causes the voltage conversion unit 12 to perform the first conversion operation so that the charging current of the power storage unit 3 becomes constant. When the charging current of the power storage unit 3 becomes constant, the control unit 16 determines in step S24 whether the power storage unit 3 is in the deteriorated state. Specifically, the control unit 16 measures the internal resistance of the power storage unit 3 based on the voltage and the charging current of the power storage unit 3. The control unit 16 calculates the rate of increase of the measured value relative to the initial value of the internal resistance of the power storage unit 3, and determines whether the calculated rate of increase exceeds the threshold value. If it is determined that the rate of increase exceeds the threshold value, the control unit 16 determines that the power storage unit 3 is in the deteriorated state. If it is determined that the rate of increase does not exceed the threshold value, the control unit 16 determines that the power storage unit 3 is not in the deteriorated state.

If it is determined that the power storage unit 3 is in the deteriorated state, the control unit 16 performs the notification processing in step S25. The notification processing is processing of notifying the external ECU that the power storage unit 3 is in the deteriorated state.

If the control unit 16 determines that the power storage unit 3 is not in the deteriorated state, or after performing the notification processing, the control unit 16 stops the first conversion operation of the voltage conversion unit 12 in step S26.

### Other Embodiments

The present disclosure is not limited to the embodiments described above with reference to the drawings. For example, features of the embodiments described above and below can be combined in any combination as long as no contradictions are present. Further, any feature of the embodiments described above and below can be omitted unless expressly stated as essential. Furthermore, the embodiments described above may be modified as follows.

In each of the above embodiments, the fourth switch 24 corresponding to the element unit may be the diode. A cathode of the diode is electrically connected to the other end of the third switch 23 and the other end of the inductor 25. An anode of the diode is electrically connected to the ground 80.

The embodiments disclosed herein should be considered in all respects as illustrative and not restrictive. The scope of the present disclosure is not limited to the embodiments disclosed herein, but is indicated by claims, and is intended to include all modifications within the meaning and scope of the claims and equivalents thereof.

1. An in-vehicle control device comprising:
a voltage conversion unit to be provided between a power storage unit and a power path that supplies power from a power supply unit to a load; and
a control unit configured to control the voltage conversion unit,
wherein the voltage conversion unit performs a first conversion operation of converting a voltage applied to a first conductive path on a power path side and applying the converted voltage to a second conductive path on a power storage unit side, and a second conversion operation of converting a voltage applied to the second conductive path and applying the converted voltage to the first conductive path,
the voltage conversion unit has a first switch and a second switch connected in series between the first conductive path and ground, a third switch and an element unit connected in series between the second conductive path and the ground, and an inductor,
the first switch is disposed closer to the first conductive path than the second switch is,
the third switch is disposed closer to the second conductive path than the element unit is,
the element unit is a fourth switch or a diode and is capable of interrupting a current flowing through the element unit toward the ground,
one end of the inductor is electrically connected to a portion between the first switch and the second switch, another end of the inductor is electrically connected to a portion between the third switch and the element unit,
the voltage conversion unit performs a discharging operation of turning the third switch on and off, interrupting the current flowing to the ground side through the element unit at least when the third switch is in an on state, and maintaining the second switch in an on state, and
the control unit causes the voltage conversion unit to perform the discharging operation when a discharging condition is satisfied.

2. The in-vehicle control device according to claim 1, wherein the control unit determines whether the power storage unit is in a deteriorated state based on a voltage and a discharging current of the power storage unit during the discharging operation.

3. The in-vehicle control device according to claim 2, wherein the control unit causes the voltage conversion unit to perform the discharging operation so that the discharging current of the power storage unit becomes constant for at least a part of a predetermined period during the discharging operation, and determines whether the power storage unit is in the deteriorated state based on the voltage and the discharging current of the power storage unit during the predetermined period.

4. The in-vehicle control device according to claim 2, wherein the discharging condition is that a start switch of a vehicle is changed to an on state.

5. The in-vehicle control device according to claim 1, wherein the control unit causes the voltage conversion unit to perform the discharging operation and then the first conversion operation, and determines whether the power storage unit is in a deteriorated state based on a voltage and a charging current of the power storage unit during the first conversion operation.

6. The in-vehicle control device according to claim 5, wherein the control unit causes the voltage conversion unit to perform the first conversion operation so that the charging current of the power storage unit becomes constant for at least a part of a predetermined period during the first conversion operation, and determines whether the power storage unit is in the deteriorated state based on the voltage and the charging current of the power storage unit during the predetermined period.

7. The in-vehicle control device according to claim 5, wherein when a start switch of a vehicle is changed to an on state, or after the start switch is changed to an on state and the control unit causes the voltage conversion unit to perform the discharging operation, the control unit causes the voltage conversion unit to perform the first conversion operation, and determines whether the power storage unit is in the deteriorated state based on the voltage and the charging current of the power storage unit during the first conversion operation.

8. The in-vehicle control device according to claim 1, wherein the discharging condition is that a start switch of a vehicle is changed to an off state.

9. The in-vehicle control device according to claim 2, wherein the control unit measures an internal resistance of the power storage unit based on the voltage and the discharging current of the power storage unit during the discharging operation, and determines that the power storage unit is in the deteriorated state when a rate of increase of a measured value with respect to an initial value of the internal resistance of the power storage unit exceeds a threshold value.

10. The in-vehicle control device according to claim 5, wherein the control unit measures an internal resistance of the power storage unit based on the voltage and the charging current of the power storage unit during the first conversion operation, and determines that the power storage unit is in the deteriorated state when a rate of increase of a measured value with respect to an initial value of the internal resistance of the power storage unit exceeds a threshold value.
